(19) United States
(12) Patent Application Publication
(10) Pub. No.: US 2009/0085111 A1
(43) Pub. Date: Apr. 2, 2009

(54) SEMICONDUCTOR DEVICE AND METHOD OF MANUFACTURING THE SAME

(75) Inventor: Yasuyuki SAYAMA, Gunma (JP)

Correspondence Address: MORRISON & FOERSTER LLP, 1650 TYSONS BOULEVARD, SUITE 400, MCLEAN, VA, 22102, US

(73) Assignees: SANYO Electric Co., Ltd., Moriguchi-shi (JP); SANYO Semiconductor Co., Ltd., Ora-gun (JP)

(21) Appl. No.: 12/238,128

(22) Filed: Sep. 25, 2008

(30) Foreign Application Priority Data
Sep. 27, 2007 (JP) 2007-252211

(51) Int. Cl. H01L 29/78; H01L 21/336

(52) U.S. Cl. 257/341; 438/268; 257/E29.263

(57) ABSTRACT

Provided is a semiconductor device and a method of manufacturing a semiconductor device. In the semiconductor device, high-concentration n type impurity regions are formed respectively below gate electrodes. By setting a gate length to be smaller than a depth of channel regions, pn junction interfaces formed of adjacent side faces of the n type impurity regions and the channel regions can be substantially vertical to a top surface of a base. With this configuration, even when reduction in size is achieved in a super junction structure, a distance between the channel regions (i.e. a current path below the gate electrode) is not reduced unnecessarily. Accordingly, an increase in resistance can be prevented. In addition, depletion layers uniformly expand in the n type semiconductor regions, and impurity concentration of the regions can be increased consequently. Accordingly, reduction in resistance can be achieved.

This application claims priority from Japanese Patent Application Number JP 2007-252211 filed on Sep. 27, 2007, the content of which is incorporated herein by reference in its entirety.

### BACKGROUND OF THE INVENTION

1. Field of the Invention

The present invention relates to a semiconductor device and a method of manufacturing the semiconductor, and, in particular, to a semiconductor device capable of achieving high breakdown voltage and low on-resistance, and a method of manufacturing the semiconductor.

2. Description of the Related Art

In a high-breakdown-voltage power metal oxide semiconductor field effect transistor (MOSFET) using semiconductor silicon, a high-resistance drift layer is provided, so that a depletion layer is expanded to enable relaxation of an electric field when a reverse voltage is applied. A technology with which resistance is reduced compared to that of a device having a conventional configuration has been proposed. In this technique, lower resistance is achieved by using, in substitution for the drift layer, a structure in which pillar-like n type semiconductor regions and p type semiconductor regions each having low resistance compared to the drift layer are alternately arranged (i.e. a super junction structure). This technology is described for instance in International Patent Publication No. WO02/067333, pamphlet.

A conventional semiconductor device and a method of manufacturing the semiconductor device will be described with reference to FIG. 13 and FIGS. 14A to 14C by taking a MOSFET as an example.

As shown in FIG. 13, a super-junction semiconductor wafer (semiconductor substrate 20) is formed by stacking, for example, an n− type semiconductor layer 22′ on an n+ type silicon semiconductor substrate 21, and then forming multiple pillar-like p− type semiconductor regions 23 with spaces between each other. Thereby, portions of n− type semiconductor layer 22′ serve respectively as pillar-like n− type semiconductor regions 22, the portions positioned between the pillar-like p− type semiconductor regions 23. Accordingly, the pillar-like p− type semiconductor regions 23 and the pillar-like n− type semiconductor regions 22 are alternately arranged. Thus, the super junction structure is obtained.

Above the p− type semiconductor regions 23, p type channel regions 24 are respectively formed. Gate electrodes 33 are disposed respectively on top surfaces of portions of the n− type semiconductor layer 22′ (n− type semiconductor regions 22) with gate insulating films 31 interposed therebetween, the portions positioned between adjacent channel regions 24. Then, the gate electrodes 33 and areas therearound are covered with interlayer insulating films 36. In addition, n+ type source regions 35 are provided respectively in top surfaces of portions of the channel regions 24 so as to be connected to a source electrode 38.

Next, a method of manufacturing the above-described MOSFET will be described with reference to FIGS. 14A to 14C.

Firstly, the semiconductor substrate 20 having a super junction structure in which the pillar-like p− type semiconductor regions 23 and n− type semiconductor regions 22 are alternately arranged (FIG. 14A) is provided. The semiconductor substrate 20 can be obtained, for example, by stacking the n− type semiconductor layer 22′ on the n+ type silicon semiconductor substrate 21 and then implanting an impurity into the n− type semiconductor layer 22′.

The gate oxide film 31 and the gate electrodes 33 are formed on top surfaces of the portions of the n− type semiconductor regions 22. Then, ions of a p type impurity (for example, boron: B) are implanted by using the gate electrodes 33 as masks. Thereafter, the p type impurity is thermally diffused, so that the p type channel regions 24 are respectively formed above the p− type semiconductor regions 23 (FIG. 14B).

After a high-concentration n type impurity is implanted into the top surfaces of the portions of the channel regions 24, the interlayer insulating film 36 is formed, and the source regions 35 are formed by diffusing the n type impurity (FIG. 14C). Thereafter, contact holes are formed between the gate electrodes 33. Then, the source electrode 38 is formed on surfaces of the source regions 35 and the channel regions 24, the surfaces exposed by the contact holes. Thus, a final structure shown in FIG. 13 is obtained.

When the n-channel MOSFET cell is formed on the wafer (semiconductor substrate) having the super junction structure, the gate electrodes 33 are formed respectively above the pillar-like n− type semiconductor regions 22 serving as current paths, and the channel regions 24 are formed respectively above the pillar-like p− type semiconductor regions 23.

In terms of the super junction structure, excellent characteristics as the super junction structure can be obtained when widths W1′ and W2′ of the pillars of the n− type semiconductor region 22 and the p− type semiconductor region 23, respectively, are each small at the cross section shown in FIG. 13 (i.e. a cross section in which multiple pn junctions formed of the pillar-like semiconductor regions 22 and 23 are each exposed vertically to a top surface of the semiconductor substrate 20).

When the MOSFET is in an OFF state, a depletion layer uniformly expands from each pn junction formed in the depth directions of the semiconductor substrate, in the directions horizontal to the substrate, so that a predetermined breakdown voltage is obtained. Accordingly, under a condition that a certain breakdown voltage is obtained, the impurity concentrations of the n− type semiconductor regions 22 and the p− type semiconductor regions 23 can be made higher when the width W1′ and the width W2′ of the pillars of the regions 22 and 23 are smaller.

Especially in the case of the above-described MOSFET in which the n− type semiconductor regions 22 serve as current paths when the MOSFET is in an ON state, resistances of the regions 22 can be reduced by increasing the impurity concentration of the regions 22.

However, since the channel regions 24 are impurity diffusion regions, diffusion in the directions horizontal to the substrate (i.e. lateral diffusion) also proceeds in accordance with the depth of the channel regions 24. Accordingly, the adjacent channel regions 24 need to be formed at desired intervals (below the gate electrodes 33). Meanwhile, in the case of the semiconductor substrate having the super junction structure, the channel regions 24 need to be formed respectively above the p− type semiconductor regions 23. For this reason, the distances between the adjacent channel regions 24 cannot be designed without any constraint.

In sum, when the widths W1′ and W2′ of the n− type semiconductor regions 22 and the p− type semiconductor regions 23 are reduced so as to achieve a reduction in on-resistance, a width W3′ of a top surface of a portion of the n type semiconductor layer 22′ between the channel regions 24 and beneath the gate electrodes 33 (i.e. each of the n− type semiconductor regions 22) decreases (the portions will be referred to as π portions 45, hereinafter). Accordingly, resistance in each current path (especially each of the π portions 45) increases. This imposes limits on reductions of the n− type semiconductor regions 22 and p− type semiconductor regions 23 in width.

### SUMMARY OF THE INVENTION

The invention provides a semiconductor device that includes a semiconductor substrate of a first general conductivity type, a plurality of first pillar-like semiconductor regions of the first general conductivity type formed on the substrate, a plurality of second pillar-like semiconductor regions of a second general conductivity type formed on the substrate so that each of the second pillar-like semiconductor regions is in contact with a corresponding first pillar-like semiconductor region, a channel region of the second general conductivity type formed in each of the second pillar-like semiconductor regions so as to have an impurity concentration higher than the second pillar-like semiconductor regions, an impurity region of the first general conductivity formed in each of the first pillar-like semiconductor regions so as to have an impurity concentration higher than the first pillar-like semiconductor regions, a gate electrode layer disposed on the channel regions and the impurity regions and having slits so that each of the slits is disposed above a corresponding impurity region, and a source region of the first general conductivity type formed in each of the channel regions.

The invention also provides a method of manufacturing a semiconductor device. The method includes providing a base including a semiconductor substrate of a first general conductivity type, a plurality of first pillar-like semiconductor regions of the first general conductivity type formed on the substrate and a plurality of second pillar-like semiconductor regions of a second general conductivity type formed on the substrate so that each of the second pillar-like semiconductor regions is in contact with a corresponding first pillar-like semiconductor region. The method also includes forming a first insulating film on the base, forming a gate electrode layer having slits on the first insulating film so that each of the slits is disposed above a corresponding first pillar-like semiconductor region, forming a channel region of the second general conductivity type in each of the second pillar-like semiconductor regions, forming an impurity region of the first general conductivity type in each of the first pillar-like semiconductor regions by implanting impurities into a first pillar-like semiconductor region through a corresponding slit, forming a source region of the first general conductivity type in each of the channel regions, and forming a second insulating film on the gate electrode layer so that the slits are filled with the second insulating film.

### BRIEF DESCRIPTION OF THE DRAWINGS

FIGS. 1A and 1B are cross-sectional views of a semiconductor device according to a preferred embodiment of the present invention.

FIGS. 2A and 2B are plan views of the semiconductor device according to the present invention.

FIGS. 3A and 3B are plan views of the semiconductor device according to the present invention.

FIGS. 4A to 4C are plan views of the semiconductor device according to the present invention.

FIG. 5 is a cross-sectional view of the semiconductor device according to the present invention.

FIG. 6 is a cross-sectional view for illustrating a method of manufacturing the semiconductor device, according to the preferred embodiment of the present invention.

FIG. 7 is a cross-sectional view for illustrating the method of manufacturing the semiconductor device, according to the preferred embodiment of the present invention.

FIG. 8 is a cross-sectional view for illustrating the method of manufacturing the semiconductor device, according to the preferred embodiment of the present invention.

FIG. 9 is a cross-sectional view for illustrating the method of manufacturing the semiconductor device, according to the preferred embodiment of the present invention.

FIG. 10 is a cross-sectional view for illustrating the method of manufacturing the semiconductor device, according to the preferred embodiment of the present invention.

FIGS. 11A and 11B are cross-sectional views for illustrating the method of manufacturing the semiconductor device, according to the preferred embodiment of the present invention.

FIG. 12 is a cross-sectional view for illustrating the method of manufacturing the semiconductor device, according to the preferred embodiment of the present invention.

FIG. 13 is a cross-sectional view of a conventional semiconductor device.

FIGS. 14A to 14C are cross-sectional views for illustrating a method of manufacturing the conventional semiconductor device.

### DESCRIPTION OF THE INVENTION

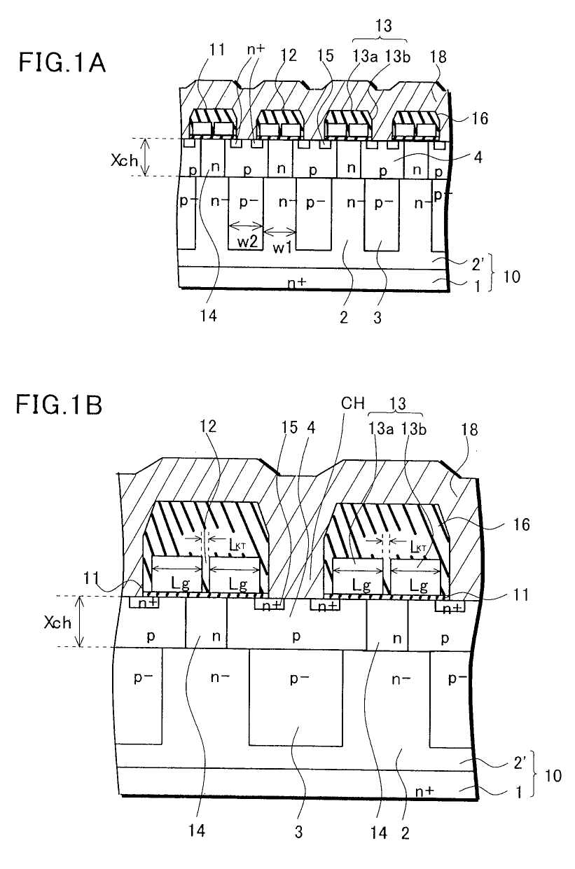

A preferred embodiment of the present invention will be described by taking an n channel MOSFET as an example, with reference to FIGS. 1A and 1B, 2A and 2B, 3A and 3B, 4A to 4C, 5 to 10, 11A and 11B, and 12.

FIGS. 1A and 1B are cross-sectional views showing a configuration of the MOSFET according to this embodiment. FIG. 1A is a cross-sectional view of multiple MOSFET cells, and FIG. 1B is an enlarged cross-sectional view of part of FIG. 1A.

The MOSFET includes a semiconductor substrate 1, one-conductivity-type semiconductor regions 2, opposite-conductivity-type semiconductor regions 3, channel regions 4, one-conductivity-type impurity regions 14, gate electrodes 13, a gate insulating film 11, interlayer insulating films 16, and source regions 15.

A base 10 has a super junction structure in which the multiple pillar-shaped n− type semiconductor regions 2 and the multiple p− type semiconductor regions 3 are alternately arranged on the n+ type silicon semiconductor substrate 1.

Here, the super junction structure is a structure in which: impurity concentrations and widths of the n− type semiconductor regions 2 and the p− type semiconductor regions 3 are selected to be desired values, respectively; and, when a reverse voltage is applied, a depletion layer expands from each of pn junctions formed of the n− type semiconductor regions 2 and the p− type semiconductor regions 3, in directions horizontal to a top surface of the base 10, and the pillar-shaped n− type semiconductor regions 2 and the p− type semiconductor regions 3 become fully depleted at the same voltage to form fully-depleted regions in the base 10.

An example of the super junction structure described herein is as follows. Specifically, an n− type semiconductor layer 2′ (epitaxial layer) is stacked on the n+ type silicon semiconductor substrate 1, for example, and the multiple pillar-like p− type semiconductor regions 3 are then formed at desired intervals. Here, the p− type semiconductor regions 3 may be impurity diffusion regions, or may be buried epitaxial layers. In addition, the p− type semiconductor regions 3 are not limited to those shown in FIGS. 1A and 1B, and may be those having a depth enough to reach the n+ type silicon semiconductor substrate 1.

It is noted that conductivity types such as n+, n and n− belong in one general conductivity type, and conductivity types such as p+, p and p− belong in another general conductivity type.

In the cross section shown in FIG. 1A, each of the n− type semiconductor regions 2 has a width W1 of 5 μm, for example, and impurity concentration of approximately 1×10¹⁶ cm⁻³. Meanwhile, each of the p− type semiconductor regions 3 has a width W2 of 5 μm, for example, and impurity concentration of approximately 1×10¹⁶ cm⁻³. The widths and the impurity concentrations are selected in accordance with breakdown voltage required for the semiconductor device.

The channel regions 4 are formed on the top surface of the base 10. The channel regions 4 are diffusion regions formed respectively above the p− type semiconductor regions 3 by implantation and diffusion of ions of a p type impurity. Moreover, the gate oxide film 11 selectively covering the top surface of the base 10 is provided, and the gate electrodes 13 are disposed on the gate oxide film 11. The interlayer insulating films 16 are provided respectively on the gate electrodes 13, so that the each of the gate electrodes 13 and an area therearound are covered with the gate oxide film 11 and the corresponding interlayer insulating film 16.

Refer to FIG. 1B. A separation hole 12 having a separation width L_{KT} is formed in a substantially central portion of each of the gate electrodes 13 as shown in FIG. 1B. Accordingly, each of the gate electrodes 13 is partially separated into two separated gate electrodes 13a and 13b by the corresponding separation hole 12, while being integrally covered with the corresponding interlayer insulating film 16. The two separated gate electrodes 13a and 13b have the same gate width L_{g}.

The source regions 15 are high concentration n type impurity regions formed in top surfaces of the channel regions 4. The source regions 15 are each formed so as to overlap part of the bottom of the corresponding gate electrode 13, and to extend outside the gate electrode 13. Moreover, the source regions 15 are each in contact with a source electrode 18 through a contact hole CH between the corresponding interlayer insulating films 16.

The n type impurity regions 14 are formed respectively on top surfaces of the pillar-like n− type semiconductor regions 2 and below the gate electrodes 13. The impurity concentration of the n type impurity regions 14 is set to be higher than approximately 1×10¹⁶ cm⁻³, which is the impurity concentration of the n− type semiconductor regions 2, and is set at, for example, approximately 1×10¹⁷ cm⁻³. The pn junction interfaces formed of adjacent side surfaces of the n type impurity regions 14 and the channel regions 4 are each substantially vertical to the top surface of the base 10. In addition, bottom parts of the n type impurity regions 14 and the channel regions 4 are positioned at a substantially same depth.

The separated gate electrodes 13a and 13b of each of the gate electrodes 13 are positioned so as to be symmetrical with respect to the corresponding n type impurity region 14. In other words, a center line of each of the separation width L_{KT} substantially conforms to that of the corresponding n type impurity region 14. In addition, the gate width L_{g} of the separated gate electrodes 13a and 13b are set to be equal to or smaller than a depth X_{ch} of the channel regions 4. Accordingly, n type impurity regions 14 which can form substantially vertical pn junction interfaces with the side surfaces of the channel regions 4, and which have a depth equal to that of the channel regions 4. This configuration will be described later in detail. In addition, a drain electrode is formed on a back surface of the substrate 1, although omitted in FIGS. 1A and 1B.

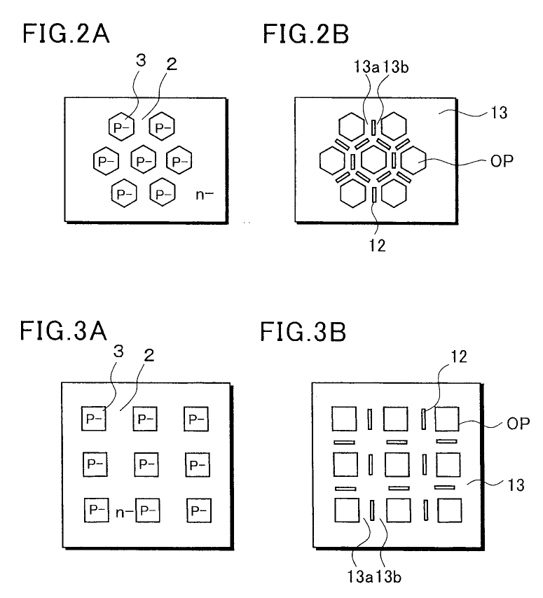

FIGS. 2A and 2B, FIGS. 3A and 3B, and FIGS. 4A to 4C show plane patterns of the pillar-like n− type semiconductor regions 2, the pillar-like p− type semiconductor regions 3, and the gate electrodes 13. FIGS. 2A, 3A, and 4A are pattern views of the n− type semiconductor regions 2 and p− type semiconductor regions 3 at the top surface of the base 10, and FIGS. 2B, 3B, and 4B are pattern views of the gate electrodes 13 at the top surface of the base 10.

Refer to FIG. 2A. The p− type semiconductor regions 3 are each in a regular hexagonal shape, and are arranged at regular intervals, so that the n− type semiconductor regions 2 integrally form a honeycomb pattern.

In this case, the gate electrodes 13 are disposed respectively above the n− type semiconductor regions 2 (n type impurity regions 14), and the p− type semiconductor regions 3 are exposed from openings OP, as shown in FIG. 2B. Each of the separation hole 12 is provided in the substantially central portion of the corresponding gate electrode 13 so as to be parallel to sides of the corresponding openings OP. The separated gate electrodes 13a and 13b positioned respectively on both sides of the corresponding separation hole 12 are integrally covered with the corresponding interlayer insulating film 16.

Refer to FIG. 3A. The p− type semiconductor regions 3 are each in a regular square shape, and are arranged at regular intervals, so that the n− type semiconductor regions 2 integrally form a grid pattern.

In this case, the gate electrodes 13 are disposed respectively above the n− type semiconductor regions 2 (n type impurity regions 14), and the p− type semiconductor regions 3 are exposed from openings OP, as shown in FIG. 3B. Each of the separation hole 12 is provided in the substantially central portion of the corresponding gate electrode 13 so as to be parallel to sides of the corresponding openings OP. The separated gate electrodes 13a and 13b positioned respectively on both sides of the corresponding separation hole 12 are integrally covered with the corresponding interlayer insulating film 16.

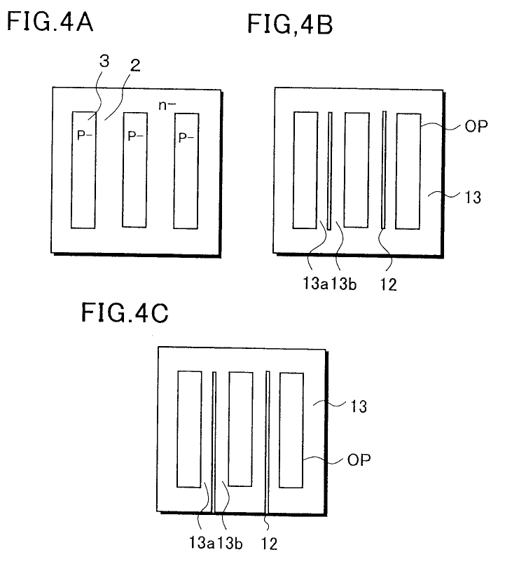

Refer to FIG. 4A. The p− type semiconductor regions 3 are each in a stripe shape, and are arranged at regular intervals, so that the n− type semiconductor regions 2 integrally form a stripe pattern.

In this case, the gate electrodes 13 are disposed respectively above the n− type semiconductor regions 2 (n type impurity regions 14), and the p− type semiconductor regions 3 are exposed from openings OP, as shown in FIG. 4B. Each of the separation holes 12 is provided in the substantially central portion of the corresponding gate electrode 13 so as to be parallel to sides of the corresponding openings OP. The separated gate electrodes 13a and 13b positioned respectively on both sides of the corresponding separation hole 12 are integrally covered with the corresponding interlayer insulating film 16.

Alternatively, one end of each of the separation holes 12 may be extended to one end portion of the corresponding gate electrode 13 so that each pair of the separation electrodes 13a and 13b can form a concave shape as shown in FIG. 4C.

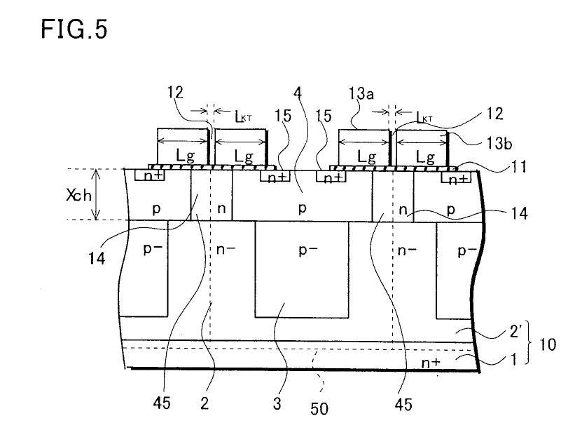

FIG. 5 is a cross-sectional view showing a state of a depletion layers 50 when a drain-source voltage is applied in an OFF state. In FIG. 5, the interlayer insulating films 16 and the source electrode 18 are omitted.

In this embodiment, the pn junction interfaces formed of adjacent side surfaces of the n type impurity regions 14 and the channel regions 4 are each substantially vertical to the top surface of the base 10. Moreover, the base parts of the n type impurity regions 14 and the channel regions 4 are positioned at a substantially same depth. In other words, the channel regions 4 are not in a shape having any curvature while being diffusion regions, so that the channel regions 4 that are adjacent to each other are equally spaced from each other both around the top surfaces and around the bottom parts. Accordingly, a reduction in width of portions between the channel regions 4 and below the gate electrodes 13 (i.e. π portions 45) due to lateral diffusion of the channel regions 4 can be prevented. Consequently, an increase in resistance in the π portions 45 can be prevented.

This configuration can be realized by forming each of the n type impurity regions 14 so as to satisfy a condition that the depletion layers 50 expanding from the channel regions 4 positioned respectively on both sides of the n type impurity region 14, toward the n type impurity region 14, become pinched-off when the MOSFET is in an OFF state. To be more specific, the n type impurity regions 14 are formed so as to satisfy a condition, gate electrode separation width L_{KT}: channel region depth X_{ch}=0.15 or smaller: 1.

With this configuration, the depletion layers 50 in each of the n type impurity regions 14 expand from the channel regions 4 positioned on both sides of the n type impurity region 14 to consequently become pinched-off, and uniformly expand in the base depth direction (vertical direction), as indicated by the broken lines in FIG. 5.

As described above, the channel regions 4 sandwiching each of the n type impurity regions 14 are uniformly spaced from each other around the top surfaces and around the bottom parts, and the depletion layers 50 can thereby be sufficiently pinched-off. Consequently, the n type impurity regions 14 can have a higher impurity concentration than that of the pillar-like n− type semiconductor regions 2.

Accordingly, even when the n− type semiconductor regions 2 and the p− type semiconductor regions 3 each reduced in width are provided in the base 10 with the super junction structure, a reduction in width of the a portions 45 due to lateral diffusion of the channel regions 4 can be prevented. Moreover, since the impurity concentrations of the π portions 45, corresponding to the n type impurity regions 14, can be increased, an increase in resistance in the π portions 45 when the MOSFET is in an ON state can be prevented.

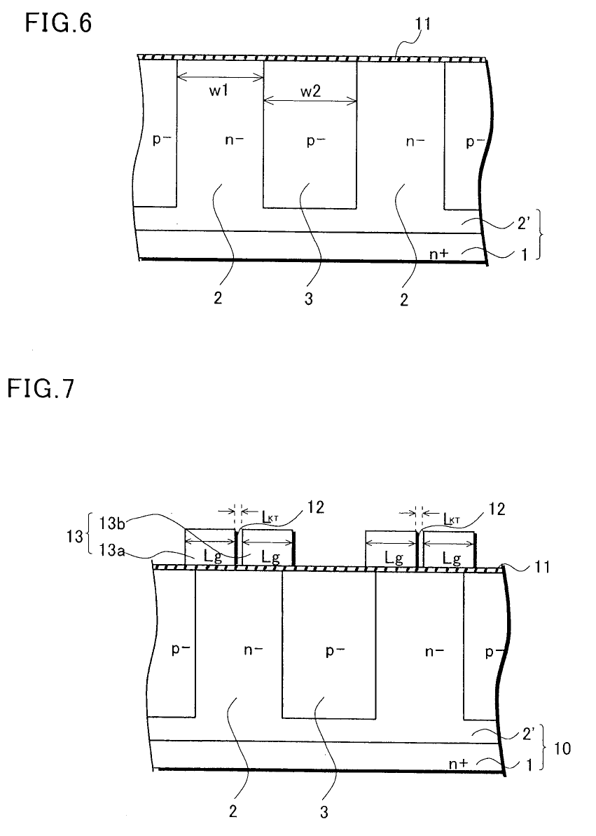

Next, a method of manufacturing a MOSFET, according to this embodiment, will be described with reference to FIGS. 6 to 10, 11A and 11B, and 12.

Step 1 (see FIG. 6): A base 10 is provided in which multiple pillar-like n− type semiconductor regions 2 and multiple pillar-like p− type semiconductor regions 3 are alternately arranged on an n+ type silicon semiconductor substrate 1.

In this embodiment, any method can be employed as long as a super junction structure with the n− type semiconductor regions 2 and the p− type semiconductor regions 3 reduced in width are alternately arranged can be obtained. Examples of such a method will be described below.

For example, an n− type semiconductor layer 2′ having a thickness shown in FIG. 6 (for example, approximately 40 μm (impurity concentration of approximately 1×10¹⁶ cm⁻³)) is formed on the n+ type silicon semiconductor substrate 1, and multiple trenches are formed at regular intervals in the n− type semiconductor layer 2′. Thereafter, the p− type semiconductor regions 3 are formed respectively in the trenches by epitaxial growth of p type silicon. Here, portions of n− type semiconductor layer 2′ which are respectively positioned between the trenches are to serve as n− type semiconductor regions 2.

Alternatively, another method may be employed. In this method, an n− type epitaxial layer having a certain thickness (for example, approximately 5 μm) is formed on the n+ type silicon semiconductor substrate 1, and ions of a p type impurity are implanted and then diffused in the n− type epitaxial layer at regular intervals. Thereafter, the step of forming an n− type epitaxial layer and the step of implanting and diffusing ions of the p type impurity are repeatedly performed for several times. Thus, the n− type semiconductor regions 2 and the p− type semiconductor regions 3 are formed.

A still another method may be employed. In this method, a trench having an opening width sufficient to have multiple pillar-like semiconductor regions arranged therein is formed in the n− type semiconductor regions. Then, a p type epitaxial layer having a film thickness equal to a pillar width is formed, etching is then performed on a surface of the p type epitaxial layer, an n type epitaxial layer having a film thickness equal to a pillar width is formed, and etching is then performed on a surface of the n type epitaxial layer, which are repeated for several times. Thus, the n− type semiconductor regions 2 and the p− type semiconductor regions 3 are repeatedly formed in the single trench.

Here, the p− type semiconductor regions 3 may be formed to each have a depth enough to reach the n+ type silicon semiconductor substrate 1.

A still another method may be employed. In this method, trenches are formed in the n− type semiconductor layer 2′ at regular intervals, ions of a p type impurity are implanted into the inner walls of the trenches, and the trenches are then each buried with an n type semiconductor layer.

At the cross section shown in FIG. 6, the n− type semiconductor regions 2 each have a pillar width W1 of 5 μm, and impurity concentration of approximately 1×10¹⁶ cm⁻³, for example. Moreover, the p− type semiconductor regions 3 each have a width W2 of 5 μm, and impurity concentration of approximately 1×10⁶ cm⁻³, for example. The widths and the impurity concentrations are selected in accordance with the breakdown voltage required of the semiconductor device.

A top surface of the base 10 is thermally oxidized (at approximately 1000° C.) to form a gate insulating film 11 to have a thickness according to a threshold value, for example, approximately 1000 Å.

Step 2 (see FIG. 7): Subsequently, a non-doped polysilicon layer is stacked on an entire surface of the gate insulating film 11, and ions of phosphorus (P), for example, are implanted so that high concentration can be obtained, and are then diffused. Thereby, high dielectric constant can be achieved. Dry etching is then performed by using a resist film of a desired pattern as a mask, to form gate electrodes 13. The gate electrodes 13 are each partially separated by a separation hole 12, to form two separated gate electrodes 13a and 13b each having the same gate width L_{g}. The width of the separation holes 12 (separation width L_{KT}) is approximately 0.6 μm, for example. Here, the gate electrodes 13 may be formed by patterning after a polysilicon doped with an impurity is stacked on the entire surface.

The gate width L_{g} of the separated gate electrodes 13a and 13b is set to be smaller than the depth of the channel regions to be described later, and is set at approximately 2.0 μm, for example.

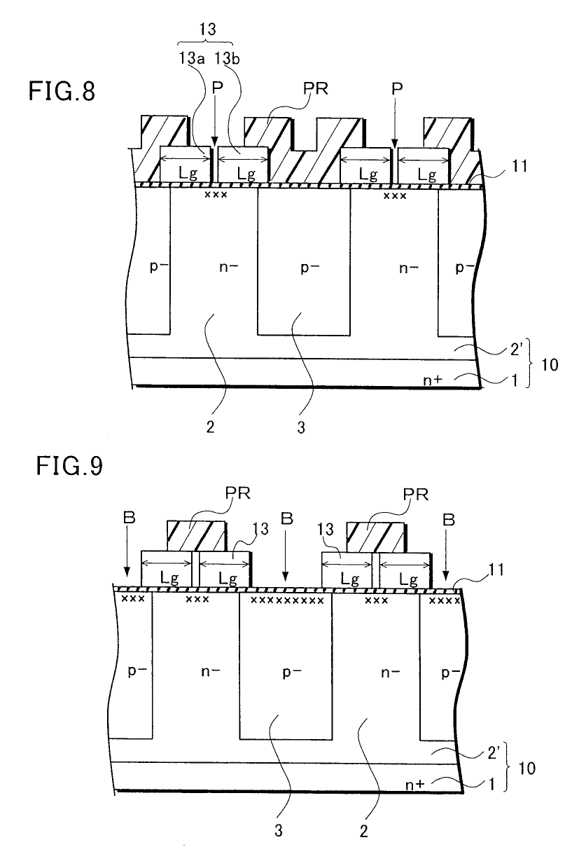

Step 3 (see FIG. 8): In this step, ions of an one-conductivity-type impurity are implanted in the separation holes of the gate electrodes. Specifically, a resist film PR is entirely formed, and patterning is then performed on the resist film PR so that the separation holes 12 and area around the separation holes 12 can be exposed. Thereafter, ions of an n type impurity (for example, phosphorus: P) are implanted by using the resist film PR as a mask. The ions of the n type impurity with a dose amount of approximately 10×10¹³ cm⁻² are implanted into the top surface of the n− type semiconductor regions 2 through portions of the gate oxide film 11 which are exposed from the separation holes 12.

Step 4 (see FIG. 9): In this step, ions of an opposite-conductivity-type impurity are implanted in order to form the channel regions. Specifically, a resist film PR is formed again, and portions of the resist film PR which cover at least the separation holes 12 are left.

Ions of a p type impurity (for example, boron: B) are implanted into portions of the top surfaces of the p− type semiconductor regions 3, the portions positioning outside the separated gate electrodes 13a and 13b. The dose amount is approximately 2.0×10¹³ cm⁻². Here, the dose amount of this p type impurity is substantially equal to that of the n type impurity in Step 3. For example, boron ions are implanted as the p type impurity, at an acceleration energy of 80 KeV, and with a dose amount of 2×10¹³ cm⁻², while phosphorus ions are implanted at an acceleration energy of 120 KeV, and with a dose amount of 1×10¹³ cm⁻², to form n type impurity regions.

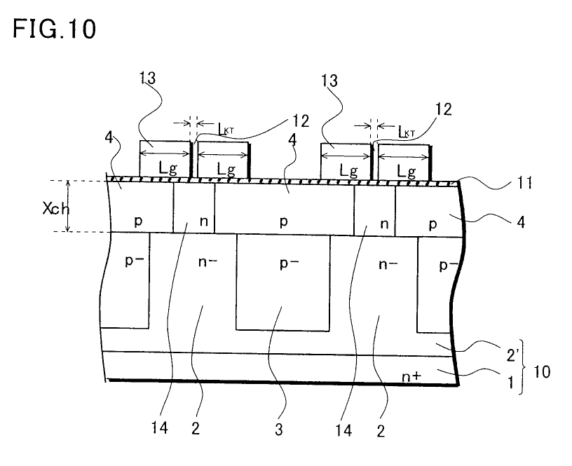

Step 5 (see FIG. 10): Thermal treatment (at 1150° C., for 180 minutes) is performed to diffuse the ions of the n type impurity and the p type impurity implanted in Step 3 and Step 4, at the same time. Thereby, multiple channel regions 4 and n type impurity regions 14 are formed.

The ions of the n type impurities implanted through the separation holes 12 are diffused in a base depth (vertical) direction, and also in lateral (horizontal) directions. Accordingly, by setting a gate length L_{g} to be equal to or smaller than a width X_{ch} of the channel regions 4, pn junction interfaces between adjacent side faces of the n type impurity regions 14 and the channel regions 4 can be formed substantially vertically to the top surface of the base 10. Moreover, by performing ion implantation under the condition of Step 4, the ions are diffused so that the bottom parts of the n type impurity regions 14 and the channel regions 4 can be positioned at a substantially same depth.

In addition, the channel regions 4 are formed so as to satisfy a condition, separation width L_{KT}: depth X_{ch} of channel regions 4=0.15 or smaller: 1. Specifically, the channel regions 4 are formed so as to satisfy conditions, L_{KT}=0.6 μm, and X_{ch}=4 μm. Thereby, depletion layers can be sufficiently pinched-off in the n type impurity regions 14.

In order that the depletion layers expanding from the n type impurity regions 14 can be sufficiently pinched-off, the n type impurity regions 14 need to be formed to have a desired depth. Here, the n type impurity regions 14 are also formed in the diffusion step for forming the channel regions 4 by implanting the ions of the one-conductivity-type impurity from the separation holes 12 after the formation of the gate electrodes 13 as described above. Thereby, the depth of the n type impurity regions 14 can be easily controlled without any influence of thermal treatment performed in the formation of the gate electrodes 13.

When the depth X_{ch} of the channel regions 4 is set to be larger in accordance with the characteristics, the ions of the p type impurity are further diffused. When the channel regions 4 are formed deeper, the width of the n type impurity regions 14 also changes. However, this does not cause any problem as long as the width is within a range in which pinch-off occurs when V_{DSS} is applied.

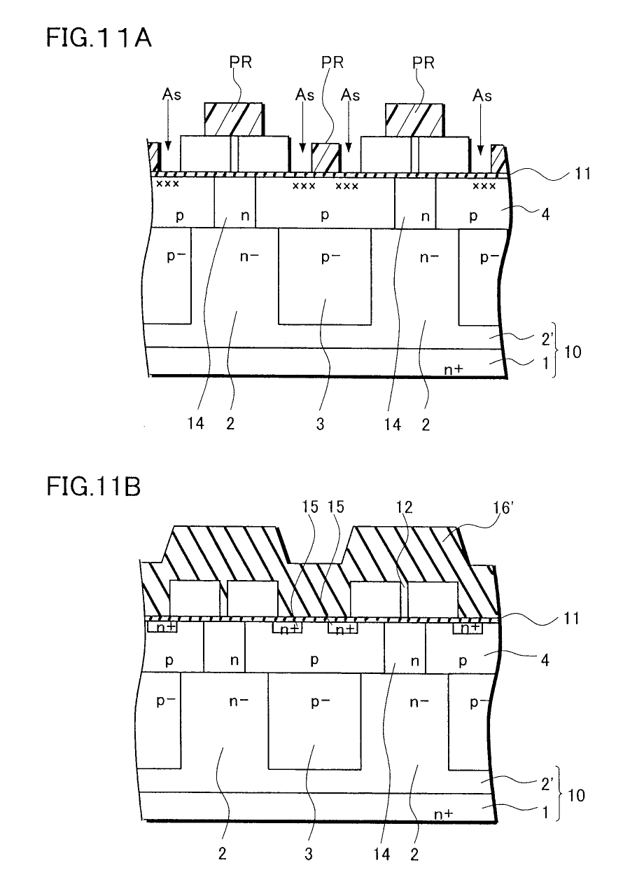

Step 6 (see FIG. 11): A mask through which portions of the channel regions 4 are exposed is formed by using a new resist film PR, and ions of an n+ type impurity (for example, arsenic: As) are implanted. Here, the implantation energy is set at approximately 100 KeV, and the dose amount is set at approximately 5×10¹⁵ cm⁻² (FIG. 11A).

Thereafter, the resist film PR is removed, and an insulating layer 16′, such as phosphorus silicate glass (PSG), to serve as interlayer insulating films are entirely stacked by a chemical vapor deposition (CVD) method. By heat treatment (at less than 1000° C., and for approximately 60 minutes), the ions of the n+ type impurity are diffused in the n+ type impurity regions, and source regions 15 are thereby formed (FIG. 11B).

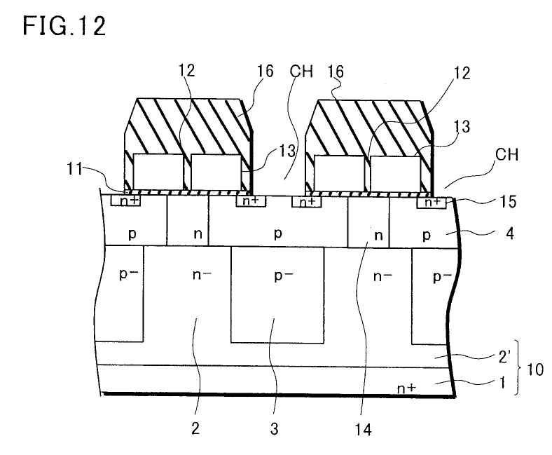

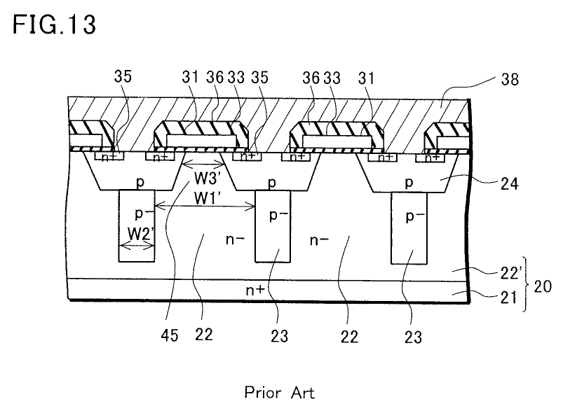

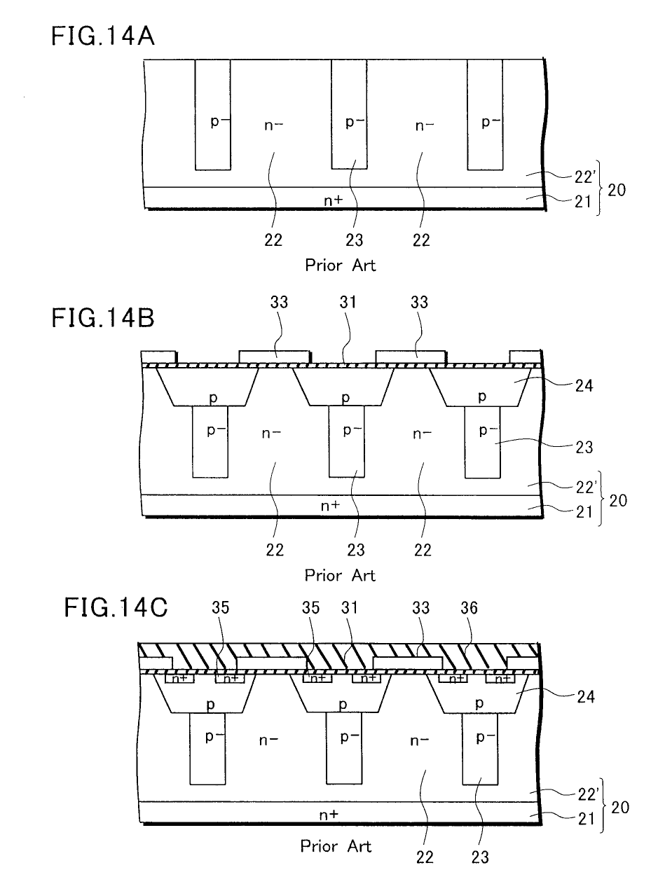

Step 7 (see FIG. 12): Etching is performed on the insulating film 16′ by using a new resist film (not shown in FIG. 12) as a mask. Thereby, interlayer insulating films 16 are left, and contact holes CH are formed. The interlayer insulating films 16 each integrally cover the corresponding separated gate electrodes 13a and 13b separated by the corresponding separation hole 12.

Thereafter, a barrier metal layer (not shown in FIG. 12) is entirely formed, and, for example, aluminum alloy is sputtered onto the barrier metal layer, so as to have a film thickness of 20000 Å to 50000 Å. By alloying heat-treatment, a source electrode 18 formed into a desired shape by patterning is formed. Thus, the final structure shown in FIG. 1 is obtained.

In this embodiment of the present invention, description has been given by taking the n channel MOSFET as an example. However, the present invention can be similarly applied to a p channel MOSFET. Moreover, application of the present invention is not limited to the above-described MOSFETs. The present invention can be similarly applied to any insulating-gate-type semiconductor element such as an insulated gate bipolar transistor (IGBT), and the same effects can be obtained by using such an element.

According to the present invention, firstly, since high-concentration n type impurity regions are provided respectively below gate electrodes, the junction interfaces between the side surfaces of channel regions and n type impurity regions can be substantially vertical to the top surface of the base. With this configuration, even when the channel regions are formed of diffusion regions, unnecessary lateral diffusion of the channel regions can be prevented. Specifically, by setting the depth X_{ch} of the channel regions to be equal to or larger than the gate length L_{g} of gate electrodes, the n type impurity regions can be formed so as to each have side surfaces forming vertical junction interfaces with side surfaces of the corresponding channel regions, and to have the same depth as that of the channel regions.

Accordingly, even when reduction in widths of pillar-like p type (p− type) semiconductor regions and n type (n− type) semiconductor regions is achieved in a semiconductor substrate having a super junction structure, an increase in resistance due to reduction in width of π portions respectively below the gate electrodes can be prevented.

In addition, reduction in size can be achieved in a super junction structure. Accordingly, impurity concentrations of the pillar-like n− type semiconductor regions and the p− type semiconductor regions can be increased in the semiconductor device according to the present invention in a case where the semiconductor has the same breakdown voltage as that having a conventional super junction structure. Consequently, resistance can be reduced in the n− type semiconductor regions to serve as current paths when the MOSFET is in an ON state. Thus, contribution can be made to achieve a reduction in on-resistance of the device.

Secondly, the π portions respectively below the gate electrodes are narrow as current paths, and tend to have high resistance in general, in a MOSFET having a planar structure. However, by setting the impurity concentration of the one-conductivity-type impurity regions formed respectively in the π portions, to be higher than that of the pillar-like n− type semiconductor regions, contribution can be made to prevent an increase in resistance in the π portions.

Specifically, by setting the separation width L_{KT} of the gate electrodes and the depth X_{ch} of the channels to satisfy the condition, separation width L_{KT} of the gate electrodes: depth X_{ch} of the channels=0.6 or smaller: 4, vertical junction interfaces can be formed, and the width of the n type impurity regions can be set at a value with which the depletion layers can be pinched-off in the n type impurity regions. Thereby, a drain-source voltage V_{DSS} of 600 V or higher can be obtained. In addition, the depletion layers are sufficiently pinched-off even around the bottom parts of the channel regions. Accordingly, the impurity concentration of the one-conductivity-type (n type) impurity regions can be increased to 1×10¹⁷ cm⁻³. Hence, a reduction in resistance in an ON state and increase in breakdown voltage in an OFF state can be achieved.

Thirdly, the one-conductivity-type impurity regions need to be formed to have a desired depth so that the depletion layers expanding from the channel regions can be sufficiently pinched-off. Since the one-conductivity-type impurity regions are formed by implanting and diffusing ions of an impurity from the separation holes formed in the gate electrodes, the depths can be easily controlled. In other words, the one-conductivity-type impurity regions are formed, after the formation of the gate electrodes, by implanting ions of the one-conductivity type impurity from the separation holes in the diffusion step for forming the channel regions. Accordingly, the depth of the one-conductivity-type impurity regions can be easily controlled without any influence of thermal treatment in the formation of the gate electrodes.

Moreover, the channel regions and the one-conductivity-type (n type) impurity regions can be formed to have the bottom portions positioned at the same depth, by controlling the dose amounts. For example, the channel regions and the n type impurity regions can be formed to have an approximately equal depth, when being formed respectively by implanting boron (acceleration energy: 80 KeV, dose amount: 2×10¹³ cm⁻²) and phosphorus (acceleration energy: 120 KeV, dose amount: 1×10¹³ cm⁻²), and then performing thermal treatment at 1150° C. In this case, the π portions results in having high impurity concentration (approximately 1×10¹⁷ cm⁻³) compared to a case where no n type impurity regions are formed in the π portions. However, since the depletion layers are pinched-off uniformly in the base depth (vertical) direction, a predetermined breakdown voltage can be obtained.

Fourthly, the one-conductivity-type impurity regions are formed by using the separation holes formed in the gate electrodes. Consequently, even when the widths of the semiconductor regions are reduced, the channel regions formed from the end portions of the gate electrodes by diffusion can be prevented from coming in contact with each other.

What is claimed is:

1. A semiconductor device comprising:
a semiconductor substrate of a first general conductivity type;
a plurality of first pillar-like semiconductor regions of the first general conductivity type formed on the substrate;
a plurality of second pillar-like semiconductor regions of a second general conductivity type formed on the substrate so that each of the second pillar-like semiconductor regions is in contact with a corresponding first pillar-like semiconductor region;
a channel region of the second general conductivity type formed in each of the second pillar-like semiconductor regions so as to have an impurity concentration higher than the second pillar-like semiconductor regions;
an impurity region of the first general conductivity formed in each of the first pillar-like semiconductor regions so as to have an impurity concentration higher than the first pillar-like semiconductor regions;
a gate electrode layer disposed on the channel regions and the impurity regions and having slits so that each of the slits is disposed above a corresponding impurity region; and
a source region of the first general conductivity type formed in each of the channel regions.

2. The semiconductor device of claim 1, wherein junction interfaces between the channel regions and the impurity regions are perpendicular to the semiconductor substrate.

3. The semiconductor device of claim 1, wherein the gate electrode layer has openings corresponding to the source regions.

4. The semiconductor device of claim 1, wherein the impurity regions and the channel regions have the same depth.

5. The semiconductor device of claim 3, wherein a width of a portion of the gate electrode layer between a slit and a corresponding opening is smaller than a depth of the channel regions.

6. The semiconductor device of claim 1, wherein a ratio of a depth of the channel regions to a width of the slits is 1 to 0.15 or smaller.

7. A method of manufacturing a semiconductor device, comprising:
providing a base comprising a semiconductor substrate of a first general conductivity type, a plurality of first pillar-like semiconductor regions of the first general conductivity type formed on the substrate and a plurality of second pillar-like semiconductor regions of a second general conductivity type formed on the substrate so that each of the second pillar-like semiconductor regions is in contact with a corresponding first pillar-like semiconductor region;
forming a first insulating film on the base;
forming a gate electrode layer having slits on the first insulating film so that each of the slits is disposed above a corresponding first pillar-like semiconductor region;
forming a channel region of the second general conductivity type in each of the second pillar-like semiconductor regions;
forming an impurity region of the first general conductivity type in each of the first pillar-like semiconductor regions by implanting impurities into a first pillar-like semiconductor region through a corresponding slit;
forming a source region of the first general conductivity type in each of the channel regions; and
forming a second insulating film on the gate electrode layer so that the slits are filled at least partially with the second insulating film.

8. The method of claim 7, wherein impurities for the channel regions and the impurities for the impurity regions are diffused at the same time.

9. The method of claim 7, wherein the gate electrode layer is formed to have openings corresponding to the source regions so that a width of a portion of the gate electrode layer between a slit and a corresponding opening is smaller than a depth of the channel regions.

10. The method of claim 7, wherein the impurity regions and the channel regions have an equal impurity concentration.

11. The method of claim 7, wherein an impurity concentration of the impurity regions is 1×10¹⁷ atoms/cm⁻³.

12. The method of claim 7, wherein the gate electrode is formed so that a ratio of a depth of the channel regions to a width of the slits is 1 to 0.15 or smaller.

13. The method of claim 7, wherein the impurity regions and the channel regions are formed to have the same depth.

14. The method of claim 7, wherein the impurity regions are formed so that junction interfaces between the channel regions and the impurity regions are perpendicular to the semiconductor substrate.
